(19) United States
(12) Patent Application Publication
(10) Pub. No.: US 2026/0221373 A1
(43) Pub. Date: Jul. 30, 2026

(54) SYSTEM, METHODS, AND APPARATUSES WITH REDUCED NOISE CURRENT

(71) Applicant: ASML Netherlands B.V., Veldhoven (NL)

(72) Inventors: Valery RAY, Methuen, MA (US); Donald BENSON, San Jose, CA (US); Zhonghua DONG, San Jose, CA (US); Li LI, San Jose, CA (US)

(73) Assignee: ASML Netherlands B.V., Veldhoven (NL)

(21) Appl. No.: 19/143,448

(22) PCT Filed: Dec. 13, 2023
(86) PCT No.: PCT/EP2023/085723

§ 371 Date: Jun. 26, 2025

Related U.S. Application Data
(60) Provisional application No. 63/435,493, filed on Dec. 27, 2022.

(51) Int. Cl. H01J 37/02; H01J 37/24; H01J 37/28; H02M 1/44

(52) U.S. Cl. CPC H01J 37/026; H01J 37/24; H01J 37/28; H02M 1/44; H01J 2237/0262

(57) ABSTRACT

Systems and apparatuses may include at least three conductors including a first conductor that is electrically isolated from a chassis, the first conductor being electrically connected to a node of an AC power source, the node of the AC power source being electrically connected to a ground reference, and the first conductor configured to provide a path for noise current generated by the EMI filter to flow to the AC power source to enable the noise current to pass to the AC power source without passing through the chassis. Each conductor may include an inductor, the inductors being magnetically coupled such that a sum of currents flowing through the inductors is substantially zero. Systems may include shielded cables electrically connected to a chamber to provide a low-impedance path for noise currents to flow, wherein at a mechanical interface, a column is mechanically coupled to and electrically isolated from the chamber.

### CROSS-REFERENCE TO RELATED APPLICATIONS

This application claims priority of U.S. application 63/435,493 which was filed on Dec. 27, 2022 and which is incorporated herein in its entirety by reference.

### FIELD

The description herein relates to the field of inspection systems, and more particularly to systems with reduced noise current.

### BACKGROUND

In manufacturing processes of integrated circuits (ICs), unfinished or finished circuit components are inspected to ensure that they are manufactured according to design and are free of defects. An inspection system utilizing an optical microscope typically has resolution down to a few hundred nanometers; and the resolution is limited by the wavelength of light. As the physical sizes of IC components continue to reduce down to sub-100 or even sub-10 nanometers, inspection systems capable of higher resolution than those utilizing optical microscopes are needed.

A charged particle (e.g., electron) beam microscope, such as a scanning electron microscope (SEM) or a transmission electron microscope (TEM), capable of resolution down to less than a nanometer, serves as a practicable tool for inspecting IC components having a feature size that is sub-100 nanometers. With a SEM, electrons of a single primary electron beam, or electrons of a plurality of primary electron beams, can be focused on locations of interest of a wafer under inspection. The primary electrons interact with the wafer and may be backscattered or may cause the wafer to emit secondary electrons. The intensity of the electron beams comprising the backscattered electrons and the secondary electrons may vary based on the properties of the internal and external structures of the wafer, and thereby may indicate whether the wafer has defects.

### SUMMARY

Embodiments of the present disclosure provide apparatuses, systems, and methods with reduced noise current. In some embodiments, systems may include a chassis; and an electromagnetic interference (EMI) filter comprising at least three conductors electrically connected to an alternating current (AC) power source, wherein: the at least three conductors include a first conductor that is electrically isolated from the chassis, the first conductor is electrically connected to a node of the AC power source, the node of the AC power source being electrically connected to a ground reference, and the first conductor is configured to provide a path for noise current generated by the EMI filter to flow to the AC power source to enable the noise current to pass to the AC power source without passing through the chassis.

Systems may include a chassis; and an EMI filter comprising at least three conductors electrically connected to an AC power source, wherein: at least one of the at least three conductors is electrically connected to the chassis and electrically connected to the AC power source, each conductor of the at least three conductors includes an inductor, the inductors being magnetically coupled such that a sum of currents flowing through the inductors is substantially zero, the at least three conductors include a first conductor that is electrically connected to a node of the AC power source, the node of the AC power source being electrically connected to a ground reference, and the first conductor is configured to provide a path for noise current generated by the EMI filter to flow to the AC power source to enable the noise current to pass to the AC power source and to enable substantially zero noise current to pass through the chassis as a result of the inductors.

Systems may include a chamber; a plurality of shielded cables that are electrically connected to the chamber to provide a low-impedance path for noise currents to flow; and a column, wherein: at a mechanical interface, the column is mechanically coupled to and electrically isolated from the chamber, and the chamber and the column are connected to a ground reference.

Systems may include a chassis; and an EMI filter comprising a conductor connected to an AC) power source, wherein: the conductor is electrically isolated from the chassis, the conductor is electrically connected to a node of the AC power source, the node of the AC power source being electrically connected to a ground reference, and the conductor is configured to provide a path for noise current generated by the EMI filter to flow to the AC power source to enable the noise current to pass to the AC power source and substantially zero noise current is injected into the chassis.

Systems may include a chassis; and an EMI filter comprising a plurality of conductors electrically connected to an AC power source, wherein: at least one of the plurality of conductors is electrically connected to the chassis and electrically connected to the AC power source, each conductor of the plurality of conductors includes an inductor, the inductors being magnetically coupled such that a sum of currents flowing through the inductors is substantially zero, the plurality of conductors comprises a first conductor that is electrically connected to a node of the AC power source, the node of the AC power source being electrically connected to a ground reference, and the first conductor is configured to provide a path for noise current generated by the EMI filter to flow to the AC power source to enable the noise current to pass to the AC power source, and the inductors being magnetically coupled enables substantially zero noise current to be injected into the chassis.

Systems may include a plurality of shielded cables that are electrically connected to a chamber to provide a path for noise currents to flow such that substantially zero of noise currents present in the plurality of shielded cables are injected into a column, wherein: at a mechanical interface, the column is mechanically connected to and electrically isolated from the chamber, and the chamber and the column are connected to a ground reference.

Systems may include a chassis; and a power supply comprising at least three conductors electrically connected to an AC power source, wherein: the at least three conductors include a first conductor that is electrically isolated from the chassis, the first conductor is electrically connected to a node of the AC power source, the node of the AC power source being electrically connected to a ground reference, and the first conductor is configured to provide a path for noise current generated by the power supply to flow to the AC power source to enable the noise current to pass to the AC power source without passing through the chassis.

Systems may include a chassis; and a power supply comprising at least three conductors electrically connected to an AC power source, wherein: at least one of the at least three conductors is electrically connected to the chassis and electrically connected to the AC power source, each conductor of the at least three conductors includes an inductor, the inductors being magnetically coupled such that a sum of currents flowing through the inductors is substantially zero, the at least three conductors include a first conductor that is electrically connected to a node of the AC power source, the node of the AC power source being electrically connected to a ground reference, and the first conductor is configured to provide a path for noise current generated by the power supply to flow to the AC power source to enable the noise current to pass to the AC power source, and the inductors being magnetically coupled enables the noise current to pass to the AC power source without passing through the chassis.

Systems may include a chassis; and a power supply comprising a conductor connected to an AC power source, wherein: the conductor is electrically isolated from the chassis, the conductor is electrically connected to a node of the AC power source, the node of the AC power source being electrically connected to a ground reference, and the conductor is configured to provide a path for noise current generated by the power supply to flow to the AC power source to enable the noise current to pass to the AC power source and substantially zero noise current is injected into the chassis.

Systems may include a chassis; and a power supply comprising a plurality of conductors electrically connected to an AC power source, wherein: at least one of the plurality of conductors is electrically connected to the chassis and electrically connected to the AC power source, each conductor of the plurality of conductors includes an inductor, the inductors being magnetically coupled such that a sum of currents flowing through the inductors is substantially zero, the plurality of conductors comprises a first conductor that is electrically connected to a node of the AC power source, the node of the AC power source being electrically connected to a ground reference, and the first conductor is configured to provide a path for noise current generated by the power supply to flow to the AC power source to enable the noise current to pass to the AC power source, and the inductors being magnetically coupled enables substantially zero noise current to be injected into the chassis.

### BRIEF DESCRIPTION OF THE DRAWINGS

FIG. 1 is a schematic diagram illustrating an exemplary electron beam inspection (EBI) system, consistent with embodiments of the present disclosure.

FIG. 2A is a schematic diagram illustrating an exemplary multi-beam system that is part of the exemplary charged particle beam inspection system of FIG. 1, consistent with embodiments of the present disclosure.

FIG. 2B is a schematic diagram illustrating an exemplary single-beam system that is part of the exemplary charged particle beam inspection system of FIG. 1, consistent with embodiments of the present disclosure.

FIG. 3 is a schematic diagram of a charged particle system.

FIG. 4 is a schematic diagram of a charged particle system, consistent with embodiments of the present disclosure.

FIG. 5A is a circuit diagram of a charged particle system, consistent with embodiments of the present disclosure.

FIG. 5B is a schematic diagram of a charged particle system, consistent with embodiments of the present disclosure.

FIG. 6 is a schematic diagram of a charged particle system, consistent with embodiments of the present disclosure.

FIG. 7 is a schematic diagram of a charged particle system.

FIG. 8 is a schematic diagram of a charged particle system, consistent with embodiments of the present disclosure.

FIG. 9 is a flowchart illustrating an exemplary process of reducing noise current, consistent with embodiments of the present disclosure.

FIG. 10 is a flowchart illustrating an exemplary process of reducing noise current, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the subject matter recited in the appended claims. For example, although some embodiments are described in the context of utilizing electron beams, the disclosure is not so limited. Other types of charged particle beams may be similarly applied. Furthermore, other imaging systems may be used, such as optical imaging, photodetection, x-ray detection, extreme ultraviolet inspection, deep ultraviolet inspection, or the like, in which they generate corresponding types of images.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional ICs. One way to monitor the process is to inspect the chip circuit structures at various stages of their formation. Inspection may be carried out using a scanning electron microscope (SEM). A SEM can be used to image these extremely small structures, in effect, taking a “picture” of the structures of the wafer. The image can be used to determine if the structure was formed properly, and also if it was formed at the proper location. If the structure is defective, then the process can be adjusted so the defect is less likely to recur. Defects may be generated during various stages of semiconductor processing. For the reason stated above, it is important to find defects accurately and efficiently as early as possible.

The working principle of a SEM is similar to a camera. A camera takes a picture by receiving and recording brightness and colors of light reflected or emitted from people or objects. A SEM takes a “picture” by receiving and recording energies or quantities of electrons reflected or emitted from the structures. Before taking such a “picture,” an electron beam may be provided onto the structures, and when the electrons are reflected or emitted (“exiting”) from the structures, a detector of the SEM may receive and record the energies or quantities of those electrons to generate an image. To take such a “picture,” some SEMs use a single electron beam (referred to as a “single-beam SEM”), while some SEMs use multiple electron beams (referred to as a “multi-beam SEM”) to concurrently take multiple “pictures” of the wafer. By using multiple electron beams, the SEM may provide more electron beams onto the structures for obtaining these multiple “pictures,” resulting in more electrons exiting from the structures. Accordingly, the detector may receive more exiting electrons simultaneously, and generate images of the structures of the wafer with a higher efficiency and a faster speed.

The generation of electron beam(s), amplification of detected signals, and processing images in a SEM requires electrical power, typically provided from an alternating current (AC) power source. AC power within charged particle systems (e.g., SEM systems) is typically distributed in the system via an unbalanced phase-neutral or phase-phase AC scheme. These distribution schemes typically have higher voltage potentials relative to the ground-referenced enclosure of the SEM, main chamber of the SEM, and body of the electron beam column in the SEM.

In typical charged particle systems, a SEM has a primary beam column that is designed to generate charged particles, form a focused probe beam, and direct the beam to a sample. The electrically conductive body of the primary beam column serves as a reference plane for the electrostatic acceleration field and a “common potential” electrode for internal particle beam optics elements, and provides a return path for particle beam currents. The primary beam column is positioned directly on the main vacuum chamber of the SEM, and the main vacuum chamber is connected to the metal enclosure and pedestal/base of the SEM.

Typical charged particle systems, however, suffer from constraints. Typically, AC power is distributed to electronic units, where it is filtered and converted to DC voltages needed for local electronic circuitry. The filtering action is accomplished, among other components, by an Electro-magnetic Interference (EMI) filter, which may include capacitors connected between AC power lines and chassis or ground reference of the electronic unit. Such capacitors could be present either as discrete elements, or as integrated components within power supplies or noise filters (e.g., EMI filter). Leakage current flowing through the filter capacitors into the chassis or ground reference of the electronic unit (e.g., via a ground connection of a filter such as an EMI filter connected to the chassis) is injected as power-line-frequency ground noise current into chassis of the SEM.

Similar to the described action of EMI filter, filtering by discrete components or by circuitry integrated into the electronic units inject power-line-frequency ground noise currents into the chassis of the SEM.

As the ground leakage current is withdrawn from AC power current supplied, because of Kirchoff's law, an equal amount of noise current is injected on the AC power distribution lines.

Electrons are directly affected by magnetic fields, therefore electron beams in a SEM are sensitive to interference from magnetic fields, including the magnetic fields generated by ground leakage current traveling within the enclosure and body of the SEM.

Some disclosed embodiments prevent or significantly reduce noise injected by one or more capacitors used for filtering the AC power, by isolating a component that contains a filter capacitor (e.g., an integrated component such as an EMI filter) from the SEM chassis or ground reference and providing a dedicated connection between the node of the capacitor (from which the injected noise originates) and the AC power source ground, such as by use of a power balance conductor. This removes or substantially reduces the ground noise current from the SEM chassis or ground reference, thus preventing it from reaching the SEM column, and therefore substantially eliminating beam distortion resulting from AC power distribution.

As previously discussed, ground leakage currents flowing through the filter capacitors may generate AC voltage noise. Some AC power cables are unshielded, thereby allowing capacitive coupling between power-line-frequency voltage noise and noise-sensitive electronics in the charged particle system.

The power imbalance current that flows through the AC power cables generates an AC magnetic field within the space surrounding the AC power cables. The AC magnetic field induces noise currents in any conductive materials (e.g., signal conductors, electronic components, SEM frame, SEM enclosures, etc.). The noise currents from the AC magnetic field flow uncontrollably through the grounded enclosure of the SEM. In a typical charged particle system, electronic components and electron beams in the SEM are connected to the grounded enclosure of the SEM. As a result, ground noise currents are injected as power-line-frequency noise into the charged particle system.

The leakage currents from the AC power that are injected into the enclosure and grounding network of the SEM uncontrollably flow through the enclosure, grounding network of the electronics, main vacuum chamber, and body of the electron beam column of the SEM. This uncontrollable flow of noise current introduces interference into the SEM column and electronics of the SEM, thereby affecting the position of the electron beam resulting in distortion of generated images.

Moreover, spurious noise currents are injected into the enclosure of the SEM due to several other factors, including the direct injection of noise currents from the surrounding facility and Eddy currents from external and internal sources of AC magnetic field interference.

For example, in a typical charged particle system, current induced in shielded cables by electromagnetic fields from the power lines flow in the shields and is transmitted to the SEM column, to which the shield is connected. The shielded cables are connected to the SEM column and inject AC ground currents from the conductive enclosure into the body of the electron beam column. As a result, ground current flows in the electron beam column. These noise currents and interferences affect the direction of charged particle beams traveling within the SEM column, thereby affecting the position of the electron beam and resulting in distortion of generated images.

While some alternative configurations exist, these alternative configurations are not sufficient to mitigate the above-described constraints. For example, the SEM column may be manufactured from mu-metal. However, mu-metal cannot protect the electron beams in the SEM column from AC magnetic fields of noise currents that flow within metal bodies of the vacuum chamber and of the SEM column. While the main chamber of the SEM may be positioned on a separate frame with a single-point grounding and without any AC-powered loads, this configuration would significantly complicate the mechanical design of the system.

One common EMI-reducing practice is bypassing ground noise currents at the entry of all cables into components of the system (e.g., electronic cabinet, module, unit, controller, chamber, etc.). However, while this technique may provide incremental improvement, it cannot eliminate injection of noise currents into the body of the SEM due to Kirchhoff's law. This technique also does not eliminate common-mode voltage noise from the unshielded power cable.

Using a solely DC power distribution is also an insufficient alternative because it would still receive and rectify power from AC mains, thereby injecting power-line-frequency interference into the enclosure and grounding network of the SEM. Using isolation transformers for each AC-powered load would be insufficient because it would rely on bulky isolation transformers, which are strong sources of power-line-frequency magnetic interference and results in a network of AC power cables having unbalanced currents.

Additional alternative configurations include using unshielded SEM control cables, interrupting shields at one side of the system, and using floating (e.g., ungrounded) circuitry for control of electron beam. While these alternative configurations may interrupt the flow of AC noise currents from the system enclosure into the body of the electron beam column, each configuration creates a new vulnerability of the SEM to electromagnetic interference. For example, unshielded control cables are susceptible to a broad spectrum of EMI, interrupting external shields makes cables susceptible to high-frequency EMI, and floating control circuitry is highly susceptible to voltage coupling of 60Hz and other EMI via capacitive coupling mechanisms.

Some of the disclosed embodiments provide systems and apparatuses that address some or all of these disadvantages by using a power balance conductor that is electrically isolated from the chassis of the system, using inductors that are magnetically coupled such that a sum of current flowing through the inductors is substantially zero, electrically coupling shielded cables to a chamber of a charged particle system, or electrically isolated a column from the chamber of the charged particle system.

Some disclosed embodiments include an AC power supply and EMI filter with a conductor that is electrically connected to a node of an AC power source, the node being connected to a ground reference and the conductor being electrically isolated from the chassis of the system. The conductor may be configured to provide a path for noise current generated by the EMI filter, discrete filter capacitors, or filter elements within an integrated power supply, to the AC power source, where the noise current may pass to the AC power source without passing through the chassis of the SEM.

Some disclosed embodiments include an AC power supply and EMI filter with a conductor that is electrically connected to the chassis of the system at the power supply and a node of an AC power source, the node being connected to a ground reference and the conductors between AC power source and AC power supply are including inductors. The inductors may be magnetically coupled such that a sum of current flowing through the inductors is substantially zero. The conductor connected to the chassis of the AC power source and a grounded node of AC power supply may be configured to provide a path for noise current generated by the EMI filter, discrete filter capacitors, or filter elements within integrated power supply to the AC power source, where the noise current may pass to the AC power source without passing through the chassis of the SEM as a result of the inductors.

Some disclosed embodiments may include a chamber, a plurality of shielded cables with external shields that are electrically connected to the chamber to provide a low-impedance path for noise currents to flow, and a column that is coupled to the chamber, the column being electrically isolated from the chamber. The chamber and the column may be connected to a ground reference.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Without limiting the scope of the present disclosure, some embodiments may be described in the context of providing detectors and detection methods in systems utilizing electron beams. However, the disclosure is not so limited. Other types of charged particle beams may be similarly applied. Furthermore, systems and methods for detection may be used in other imaging systems, such as optical imaging, photon detection, x-ray detection, ion detection, etc.

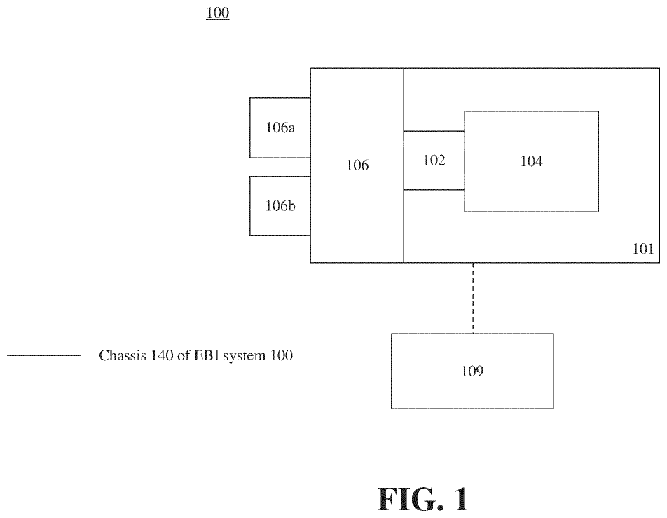

FIG. 1 illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, an electron beam tool 104, and an equipment front end module (EFEM) 106. In some embodiments, the plurality of interconnected enclosures within EBI system 100 may be referred to as chassis 140. Electron beam tool 104 is located on, or otherwise attached to, main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system.

A controller 109 is electronically connected to electron beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

Embodiments of this disclosure may provide a single charged-particle beam imaging system (“single-beam system”). Compared with a single-beam system, a multiple charged-particle beam imaging system (“multi-beam system”) may be designed to optimize throughput for different scan modes. Embodiments of this disclosure provide a low-noise multi-beam system with the capability of optimizing throughput for different scan modes by using beam arrays with different geometries and adapting to different throughputs and resolution requirements.

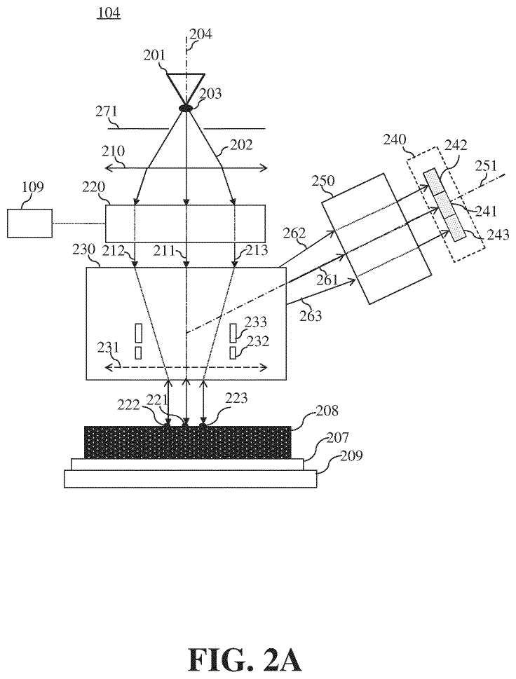

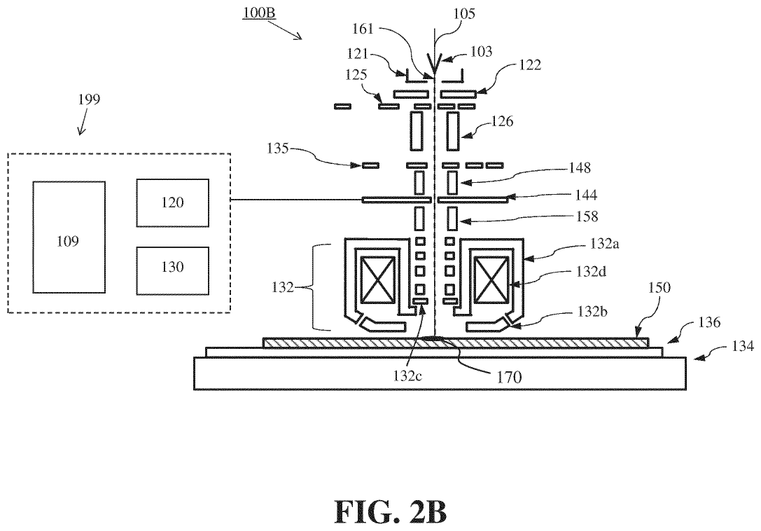

Reference is now made to FIG. 2A, which is a schematic diagram illustrating an exemplary electron beam tool 104 including a multi-beam inspection tool that is part of the EBI system 100 of FIG. 1, consistent with embodiments of the present disclosure. In some embodiments, electron beam tool 104 may be operated as a single-beam inspection tool that is part of EBI system 100 of FIG. 1. Multi-beam electron beam tool 104 (also referred to herein as apparatus 104) comprises an electron source 201, a Coulomb aperture plate (or “gun aperture plate”) 271, a condenser lens 210, a source conversion unit 220, a primary projection system 230, a motorized stage 209, and a sample holder 207 supported by motorized stage 209 to hold a sample 208 (e.g., a wafer or a photomask) to be inspected. Multi-beam electron beam tool 104 may further comprise a secondary projection system 250 and an electron detection device 240. Primary projection system 230 may comprise an objective lens 231. Electron detection device 240 may comprise a plurality of detection elements 241, 242, and 243. A beam separator 233 and a deflection scanning unit 232 may be positioned inside primary projection system 230.

Electron source 201, Coulomb aperture plate 271, condenser lens 210, source conversion unit 220, beam separator 233, deflection scanning unit 232, and primary projection system 230 may be aligned with a primary optical axis 204 of apparatus 104. Secondary projection system 250 and electron detection device 240 may be aligned with a secondary optical axis 251 of apparatus 104.

Electron source 201 may comprise a cathode (not shown) and an extractor or anode (not shown), in which, during operation, electron source 201 is configured to emit primary electrons from the cathode and the primary electrons are extracted or accelerated by the extractor and/or the anode to form a primary electron beam 202 that form a primary beam crossover (virtual or real) 203. Primary electron beam 202 may be visualized as being emitted from primary beam crossover 203.

Source conversion unit 220 may comprise an image-forming element array (not shown), an aberration compensator array (not shown), a beam-limit aperture array (not shown), and a pre-bending micro-deflector array (not shown). In some embodiments, the pre-bending micro-deflector array deflects a plurality of primary beamlets 211, 212, 213 of primary electron beam 202 to normally enter the beam-limit aperture array, the image-forming element array, and an aberration compensator array. In some embodiments, apparatus 104 may be operated as a single-beam system such that a single primary beamlet is generated. In some embodiments, condenser lens 210 is designed to focus primary electron beam 202 to become a parallel beam and be normally incident onto source conversion unit 220. The image-forming element array may comprise a plurality of micro-deflectors or micro-lenses to influence the plurality of primary beamlets 211, 212, 213 of primary electron beam 202 and to form a plurality of parallel images (virtual or real) of primary beam crossover 203, one for each of the primary beamlets 211, 212, and 213. In some embodiments, the aberration compensator array may comprise a field curvature compensator array (not shown) and an astigmatism compensator array (not shown). The field curvature compensator array may comprise a plurality of micro-lenses to compensate field curvature aberrations of the primary beamlets 211, 212, and 213. The astigmatism compensator array may comprise a plurality of micro-stigmators to compensate astigmatism aberrations of the primary beamlets 211, 212, and 213. The beam-limit aperture array may be configured to limit diameters of individual primary beamlets 211, 212, and 213. FIG. 2A shows three primary beamlets 211, 212, and 213 as an example, and it is appreciated that source conversion unit 220 may be configured to form any number of primary beamlets. Controller 109 may be connected to various parts of EBI system 100 of FIG. 1, such as source conversion unit 220, electron detection device 240, primary projection system 230, or motorized stage 209. In some embodiments, as explained in further details below, controller 109 may perform various image and signal processing functions. Controller 109 may also generate various control signals to govern operations of the charged particle beam inspection system.

Condenser lens 210 is configured to focus primary electron beam 202. Condenser lens 210 may further be configured to adjust electric currents of primary beamlets 211, 212, and 213 downstream of source conversion unit 220 by varying the focusing power of condenser lens 210. Alternatively, the electric currents may be changed by altering the radial sizes of beam-limit apertures within the beam-limit aperture array corresponding to the individual primary beamlets. The electric currents may be changed by both altering the radial sizes of beam-limit apertures and the focusing power of condenser lens 210. Condenser lens 210 may be an adjustable condenser lens that may be configured so that the position of its first principal plane is movable. The adjustable condenser lens may be configured to be magnetic, which may result in off-axis beamlets 212 and 213 illuminating source conversion unit 220 with rotation angles. The rotation angles change with the focusing power or the position of the first principal plane of the adjustable condenser lens. Condenser lens 210 may be an anti-rotation condenser lens that may be configured to keep the rotation angles unchanged while the focusing power of condenser lens 210 is changed. In some embodiments, condenser lens 210 may be an adjustable anti-rotation condenser lens, in which the rotation angles do not change when its focusing power and the position of its first principal plane are varied.

Objective lens 231 may be configured to focus beamlets 211, 212, and 213 onto a sample 208 for inspection and may form, in the current embodiments, three probe spots 221, 222, and 223 on the surface of sample 208. Coulomb aperture plate 271, in operation, is configured to block off peripheral electrons of primary electron beam 202 to reduce Coulomb effect. The Coulomb effect may enlarge the size of each of probe spots 221, 222, and 223 of primary beamlets 211, 212, 213, and therefore deteriorate inspection resolution.

Beam separator 233 may, for example, be a Wien filter comprising an electrostatic deflector generating an electrostatic dipole field and a magnetic dipole field (not shown in FIG. 2A). In operation, beam separator 233 may be configured to exert an electrostatic force by electrostatic dipole field on individual electrons of primary beamlets 211, 212, and 213. The electrostatic force is equal in magnitude but opposite in direction to the magnetic force exerted by magnetic dipole field of beam separator 233 on the individual electrons. Primary beamlets 211, 212, and 213 may therefore pass at least substantially straight through beam separator 233 with at least substantially zero deflection angles.

Deflection scanning unit 232, in operation, is configured to deflect primary beamlets 211, 212, and 213 to scan probe spots 221, 222, and 223 across individual scanning areas in a section of the surface of sample 208. In response to incidence of primary beamlets 211, 212, and 213 or probe spots 221, 222, and 223 on sample 208, electrons emerge from sample 208 and generate three secondary electron beams 261, 262, and 263. Each of secondary electron beams 261, 262, and 263 typically comprise secondary electrons (having electron energy ≤50 eV) and backscattered electrons (having electron energy between 50 eV and the landing energy of primary beamlets 211, 212, and 213). Beam separator 233 is configured to deflect secondary electron beams 261, 262, and 263 towards secondary projection system 250. Secondary projection system 250 subsequently focuses secondary electron beams 261, 262, and 263 onto detection elements 241, 242, and 243 of electron detection device 240. Detection elements 241, 242, and 243 are arranged to detect corresponding secondary electron beams 261, 262, and 263 and generate corresponding signals which are sent to controller 109 or a signal processing system (not shown), e.g., to construct images of the corresponding scanned areas of sample 208.

In some embodiments, detection elements 241, 242, and 243 detect corresponding secondary electron beams 261, 262, and 263, respectively, and generate corresponding intensity signal outputs (not shown) to an image processing system (e.g., controller 109). In some embodiments, each detection element 241, 242, and 243 may comprise one or more pixels. The intensity signal output of a detection element may be a sum of signals generated by all the pixels within the detection element.

In some embodiments, controller 109 may comprise image processing system that includes an image acquirer (not shown), a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detection device 240 of apparatus 104 through a medium such as an electrical conductor, optical fiber cable, portable storage media, IR, Bluetooth, internet, wireless network, wireless radio, among others, or a combination thereof. In some embodiments, the image acquirer may receive a signal from electron detection device 240 and may construct an image. The image acquirer may thus acquire images of sample 208. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, the image acquirer may acquire one or more images of a sample based on an imaging signal received from electron detection device 240. An imaging signal may correspond to a scanning operation for conducting charged particle imaging. An acquired image may be a single image comprising a plurality of imaging areas. The single image may be stored in the storage. The single image may be an original image that may be divided into a plurality of regions. Each of the regions may comprise one imaging area containing a feature of sample 208. The acquired images may comprise multiple images of a single imaging area of sample 208 sampled multiple times over a time sequence. The multiple images may be stored in the storage. In some embodiments, controller 109 may be configured to perform image processing steps with the multiple images of the same location of sample 208.

In some embodiments, controller 109 may include measurement circuitries (e.g., analog-to-digital converters) to obtain a distribution of the detected secondary electrons. The electron distribution data collected during a detection time window, in combination with corresponding scan path data of each of primary beamlets 211, 212, and 213 incident on the wafer surface, can be used to reconstruct images of the wafer structures under inspection. The reconstructed images can be used to reveal various features of the internal or external structures of sample 208, and thereby can be used to reveal any defects that may exist in the wafer.

In some embodiments, controller 109 may control motorized stage 209 to move sample 208 during inspection of sample 208. In some embodiments, controller 109 may enable motorized stage 209 to move sample 208 in a direction continuously at a constant speed. In other embodiments, controller 109 may enable motorized stage 209 to change the speed of the movement of sample 208 over time depending on the steps of scanning process.

Although FIG. 2A shows that apparatus 104 uses three primary electron beams, it is appreciated that apparatus 104 may use one, two, or more number of primary electron beams. The present disclosure does not limit the number of primary electron beams used in apparatus 104. In some embodiments, apparatus 104 may be a SEM used for lithography. In some embodiments, electron beam tool 104 may be a single-beam system or a multi-beam system.

For example, as shown in FIG. 2B, an electron beam tool 100B (also referred to herein as apparatus 100B) may be a single-beam inspection tool that is used in EBI system 10, consistent with embodiments of the present disclosure. Apparatus 100B includes a wafer holder 136 supported by motorized stage 134 to hold a wafer 150 to be inspected. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In an imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered primary particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 100B through a medium such as an electrical conductor, optical fiber cable, portable storage media, IR, Bluetooth, internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses are used for controlling the electron beam. For example, first quadrupole lens 148 can be controlled to adjust the beam current and second quadrupole lens 158 can be controlled to adjust the beam spot size and beam shape.

FIG. 2B illustrates a charged particle beam apparatus in which an inspection system may use a single primary beam that may be configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150.

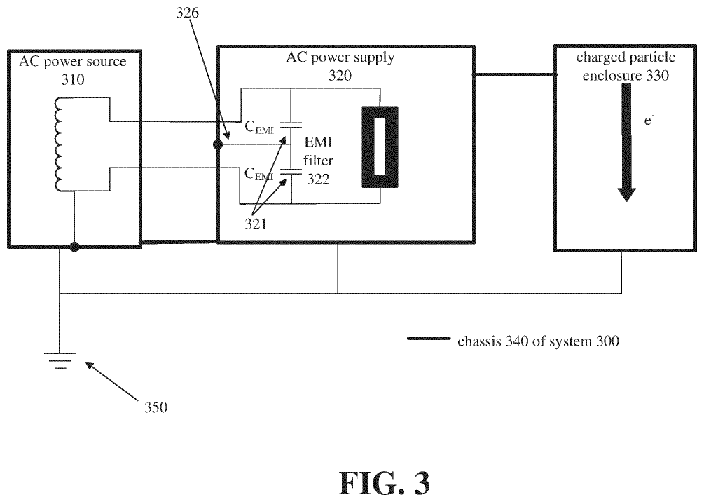

Reference is now made to FIG. 3, a schematic diagram of a charged particle system 300. Charged particle system 300 may include an alternating current (AC) power source 310, an AC power supply 320, and a charged particle enclosure (e.g., SEM enclosure) 330. Charged particle enclosure 330 may include a charged particle column (e.g., SEM column). Chassis 340 may be connected to a ground reference 350 and may enclose AC power source 310, AC power supply 320, and charged particle enclosure 330. AC power supply 320 may include an electromagnetic interference (EMI) filter 322 and EMI filter 322 may include capacitors 321 and inductors (not shown in FIG. 3). EMI filter 322 may include a conductor 326 that is electrically connected to chassis 340.

The electrons and electronic components in charged particle enclosure 330 are sensitive to interference from magnetic fields, including the magnetic fields generated by ground noise current traveling within chassis 340. In systems such as system 300, EMI filter 322 may generate noise currents (e.g., capacitor leakage current from capacitors 321, ground leakage currents). The noise currents generated by EMI filter 322 flow uncontrollably through chassis 340, thereby creating magnetic fields in charged particle enclosure 330. As a result, noise currents are injected as power-line-frequency noise into charged particle enclosure 330, affecting the electrons within SEM column (e.g., electron beam tool 104 of FIG. 1) and electronic components in charged particle enclosure 330 (e.g., controller 109 of FIG. 1, FIG. 2A, and FIG. 2B).

For example, the injected noise currents directly induce noise onto electron beams (e.g., by deflecting electron beams, by changing the shape of electron beams, by changing the focus of electron beams etc.) and induce noise into signals that transfer through cables (e.g., the noise currents may travel through the shields of cables, which may be connected to electronic components that control or affect electron beams, such as deflectors or coils of lenses). As a result, images generated by system 300 may not have the targeted image resolution since image resolution depends on characteristics of electron beams (e.g., where electron beams land on a sample, size of electron beams, etc.).

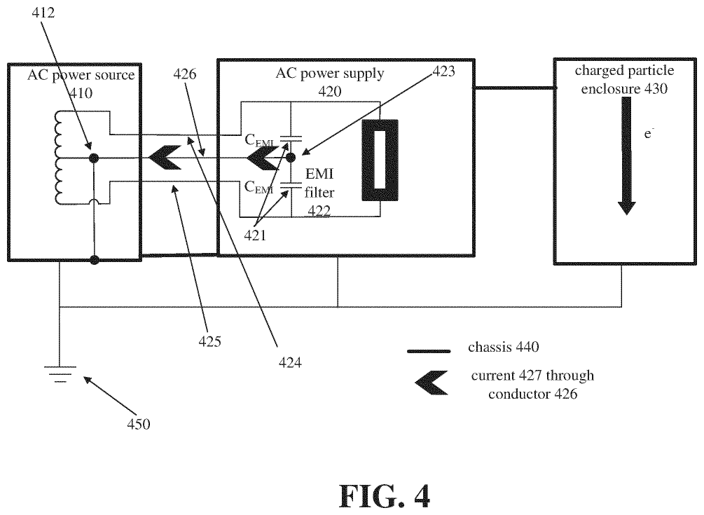

Reference is now made to FIG. 4, a schematic diagram of a charged particle system 400, consistent with embodiments of the present disclosure. In some embodiments, charged particle system 400 may include an AC power source 410, an AC powered unit (e.g., an AC power supply, AC-powered load, AC-powered device such as an AC motor, etc. or any combination thereof), and a charged particle enclosure (e.g., SEM enclosure) 430. In some embodiments, the AC powered unit may include an AC power supply 420. Charged particle enclosure 430 may include a charged particle column (e.g., SEM column). In some embodiments, chassis 440 may be connected to a ground reference 450 and may enclose AC power source 410, AC power supply 420, and charged particle enclosure 430. AC power supply 420 may include an electromagnetic interference (EMI) filter 422, which may include capacitors 421 and inductors (not shown in FIG. 4). In some embodiments, EMI filter 422 may include conductors 424, 425, and 426 (e.g., wires, cables, etc.). While three conductors are shown in FIG. 4, it should be understood that embodiments of the present disclosure may include more than three conductors. As shown in FIG. 4, conductors 424, 425, and 426 may be connected to AC power source 410.

In some embodiments, conductor 426 may be a power balance conductor that is electrically isolated from chassis 440 (e.g., in AC power supply 420). In some embodiments, conductor 426 may be connected to node 412 of AC power source 410. In some embodiments, due to its electrical isolation from chassis 440, conductor 426 may be configured to provide a dedicated path from node 423 for noise currents 427 (e.g., capacitor leakage current) generated by EMI filter 422 or other components of AC power supply 420. Depending on the topology and design of AC power supply 420, a typical range for such noise currents may be from a single milliampere to hundreds of milliamperes. In some embodiments, a sum current of node 412 may be substantially zero due to the sum current across conductors 424, 425, and 426 being substantially zero. Residual noise currents flowing between sum node 412 and the chassis are usually in the sub-milliampere range, typically between a single microampere to 100 microamperes. That is, conductor 426 may remove noise currents from chassis 440 such that substantially zero noise currents are injected into chassis 440 or ground reference 450. Instead, noise currents pass to AC power source 410 through conductor 426. As a result, ground noise currents and noise generated by said currents and magnetic fields associated with the currents injected into system 400 (e.g., into charged particle enclosure 430, into a SEM column of charged particle enclosure 430, into electronic components of charged particle enclosure 430, etc.) may be reduced. Charged particle system 400 may reduce noise currents by a factor of two to four orders of magnitude (e.g., 100-1000 times) relative to typical systems (e.g., charged particle system 300 of FIG. 3).

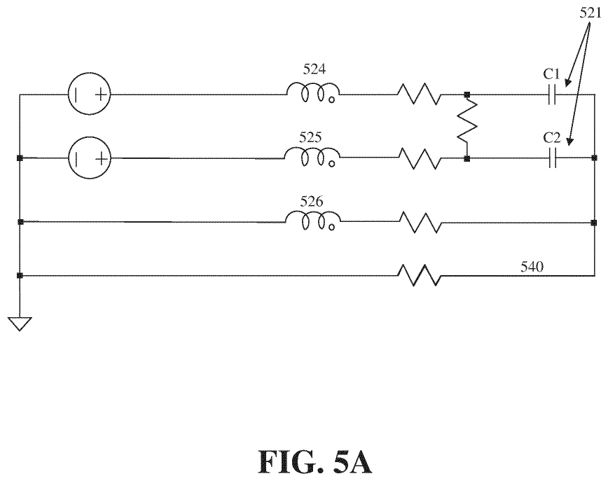

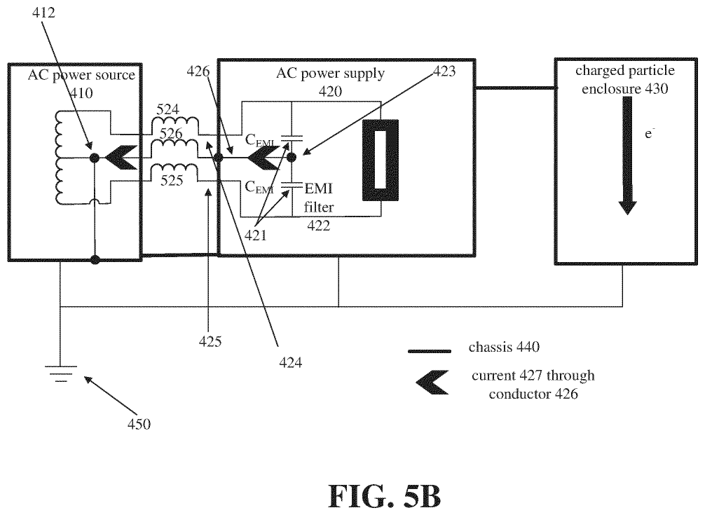

Reference is now made to FIG. 5A, a circuit diagram 500A of a charged particle system, consistent with embodiments of the present disclosure. In some embodiments, circuit diagram 500A may be used in a system similar to charged particle system 400 of FIG. 4, except that conductor 426 of the EMI filter is electrically connected to chassis 540. Circuit diagram 500A may include capacitors 521 of an EMI filter, where the EMI filter is connected to an AC power source. In some embodiments, circuit diagram 500A may include inductor components inserted into the conductors (e.g., conductors 424, 425, and 426 of FIG. 4) of an EMI filter (e.g., EMI filter 422 of FIG. 4). For example, inductor components may include inductor 524 of a first conductor of an EMI filter, an inductor 525 of a second conductor of the EMI filter, and an inductor 526 of a third conductor of the EMI filter.

In some embodiments, inductors 524, 525, and 526 may be magnetically coupled (e.g., have a common core) such that a sum of current flowing through inductors 524, 525, and 526 is substantially zero. In some embodiments, inductors 524, 525, and 526 may act as a noise current transformer (e.g., a choke) that forces the sum of currents flowing through inductors 524, 525, and 526 to be substantially zero. While circuit diagram 500A shows three inductor coils, it should be understood that circuit 500A is not limited to three inductor coils and that more inductor coils may be included.

In some embodiments, as a result of inductors 524, 525, and 526, substantially zero current may pass through a node of the AC power source connected to a ground reference such that substantially zero noise current is injected into chassis 540. As a result, ground noise current and generated by the said noise magnetic field interference injected into a charged particle enclosure (e.g., into a SEM column of the charged particle enclosure, into electronic components of the charged particle enclosure, etc.) may be reduced. For example, the sum of currents flowing through inductors 524, 525, and the balance current flowing through inductor 526 may have substantially equal magnitudes and substantially opposite phases, thus substantially cancelling noise currents generated by the EMI filter and reducing ground noise current injection into the chassis to a sub-milliampere range, typically 100 microamperes or less.

In some embodiments, at least one of the conductors of the EMI filter may be configured to provide a dedicated path from a node of the AC power supply for noise currents (e.g., capacitor leakage current generated by the EMI filter) generated by the EMI filter or other components of the AC power supply.

Reference is now made to FIG. 5B, a schematic diagram of a charged particle system 500B, consistent with embodiments of the present disclosure. Charged particle system 500B may include the same components as shown in charged particle system 400 of FIG. 4, with the addition of inductors 524, 525, and 526 described above in circuit diagram 500A of FIG. 5A.

In some embodiments charged particle system 500B may have electrical connections between current balance conductor 426 and chassis 440 at the enclosure of AC power supply 420.

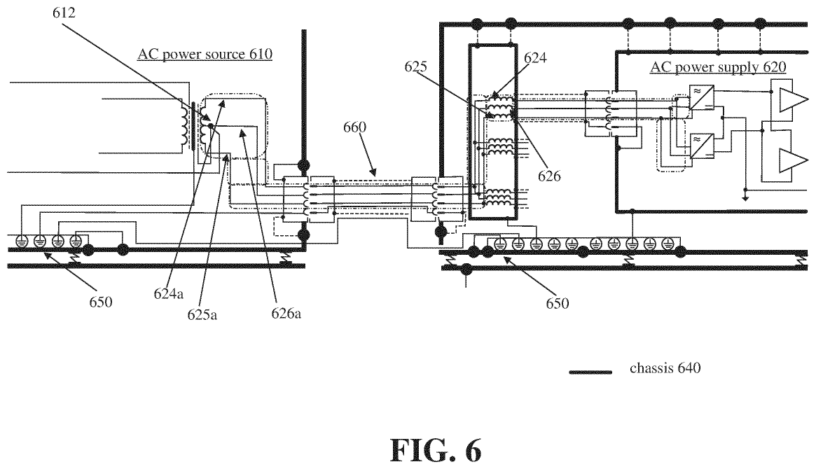

Reference is now made to FIG. 6, a schematic diagram of a charged particle system 600, consistent with embodiments of the present disclosure, including circuit diagram 500A of FIG. 5A and charged particle system 500B of FIG. 5B.

In some embodiments, charged particle system 600 may include an AC power source 610, an AC powered unit (e.g., an AC power supply, AC-powered load, AC-powered device such as an AC motor, etc. or any combination thereof), and a charged particle enclosure (e.g., SEM enclosure, not shown in FIG. 6). In some embodiments, the AC powered unit may include an AC power supply 620. AC power supply 620 may include an EMI filter or filter capacitors (not shown in FIG. 6) The charged particle enclosure may include a charged particle column (e.g., SEM column). In some embodiments, a chassis 640 (e.g., chassis 540 of FIG. 5A or chassis 440 of FIG. 5B) may be connected to ground references 650 and may enclose AC power source 610, AC power supply 620, and the charged particle enclosure. AC power supply 620 may include an EMI filter (not shown in FIG. 6). In some embodiments, the EMI filter may include conductors 624a, 625a, and 626a (e.g., wires, cables, etc.). While three conductors are shown in FIG. 6, it should be understood that embodiments of the present disclosure may include more than three conductors. As shown in FIG. 6, conductors 624a, 625a, and 626a may be connected to AC power source 610.

In some embodiments, conductors 624a, 625a, and 626a of the EMI filter or filter capacitors within AC power supply 620 may be electrically connected to chassis 640. In some embodiments, conductor 624a may include an inductor 624 (e.g., inductor 524 of FIG. 5A and FIG. 5B), conductor 625a may include an inductor 625 (e.g., inductor 525 of FIG. 5A and FIG. 5B), and conductor 626a may include an inductor 626 (e.g., inductor 526 of FIG. 5A and FIG. 5B).

In some embodiments, inductors 624, 625, and 626 may be magnetically coupled (e.g., have a common core) such that a sum of current flowing through inductors 624, 625, and 626 is substantially zero. In some embodiments, inductors 624, 625, and 626 may act as a noise current transformer (e.g., a choke) that forces the sum of current flowing through inductors 624, 625, and 626 to be substantially zero. While system 600 shows three inductor coils for three conductors, it should be understood that system 600 is not limited to three inductor coils for three conductors and that more inductor coils may be included.

In some embodiments, as a result of inductors 624, 625, and 626, substantially zero current may pass through a node 612 of AC power source 610 connected to ground reference 650 such that substantially zero noise current is injected into chassis 640. As a result, ground noise current and the noise generated by said noise current magnetic field interference injected into a charged particle enclosure (e.g., into a SEM column of the charged particle enclosure, into electronic components of the charged particle enclosure, etc.) may be reduced. For example, the sum of currents flowing through inductors 624 and 625, and the power balance current through inductor 626 may have substantially equal magnitudes (e.g., between 1 mA to 500 mA) and substantially opposite phases, thus cancelling leakage currents generated by the EMI filter, filter capacitors, or other components of AC power supply 620.

In some embodiments, at least one of the conductors of the EMI filter or AC power supply 620 may be configured to provide a dedicated path from a node of AC power supply 620 for noise currents (e.g., capacitor leakage current) generated by the EMI filter or other components of the AC power supply.

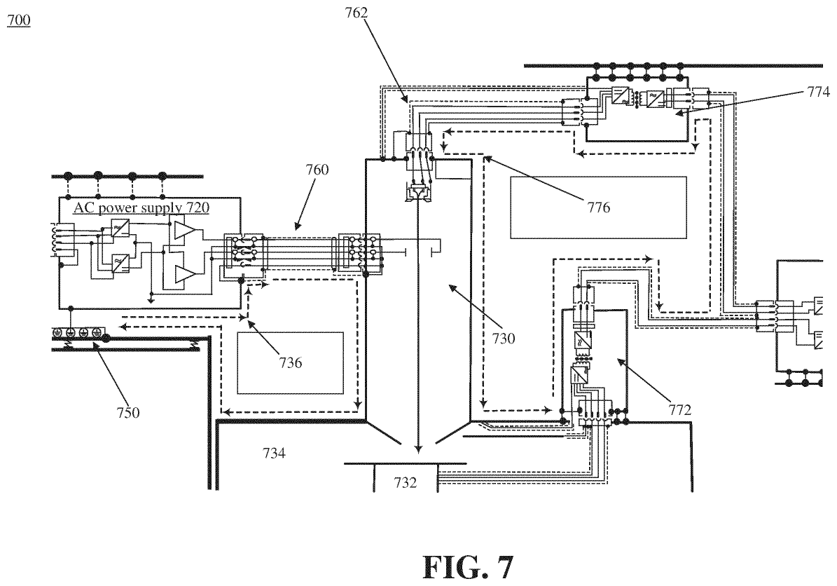

Reference is now made to FIG. 7, a schematic diagram of a charged particle system 700. Charged particle system 700 may include an AC power source (not shown in FIG. 7), an AC power supply 720, and a charged particle enclosure (e.g., SEM enclosure). The charged particle enclosure may include a charged particle column 730 (e.g., SEM column), a sample 732 (e.g., a wafer), and a main chamber 734 (e.g., a vacuum chamber). The chassis of system 700 may be connected to ground references 750 and may enclose the AC power source, AC power supply 720, charged particle column 730, and main chamber 734. AC power supply 720 may include an EMI filter (not shown in FIG. 7). System 700 may include shielded power cables 760 coupled between AC power supply 720 with other electronic modules powered by AC power supply 720 and charged particle column 730 and shielded power cables 762 coupled between charged particle column 730 and electronic components 774.

The power imbalance (i.e., ground noise) currents that flow through or are connected to the enclosure, chassis, or conductive components of system 700, such as shielded power cables 760 and 762 and electronic components 772 and 774, may be injected into and flow though the conductive body of charged particle column 730.

Furthermore, AC currents present within charged particle system 700 may generate AC magnetic fields within the space surrounding the conductive components. The AC magnetic fields induce noise currents, such as noise currents 736 and 776, in any conductive materials (e.g., signal conductors, electronic components, SEM frame, SEM enclosures, etc.). For example, noise currents 736 and 776 from the magnetic fields flow uncontrollably in loops surrounding the grounded charged particle enclosure containing charged particle column 730 and main chamber 734. Noise currents 776 flow uncontrollably in loops surrounding the electronic components, such as electronic components 772 and 774, and electron beams in charged particle column 730 or main chamber 734. As a result, ground noise currents are injected as power-line-frequency noise into charged particle column 730 and main chamber 734.

These uncontrollable ground loops of noise current introduce interference into charged particle column 730 and electronic components associated with charged particle column 730 (e.g., controller 109 of FIG. 1, FIG. 2A, and FIG. 2B), thereby affecting the position of electron beams and images generated by the charged particle enclosure. For example, the injected noise currents directly induce noise onto electron beams (e.g., by deflecting electron beams, by changing the shape of electron beams, by changing the focus of electron beams etc.) and induce noise into signals that transfer through cables (e.g., noise currents 736 and 776 may travel through shielded power cables 760 and electronic components associated with charged particle column 730), which may be connected to electronic components that control or affect electron beams, such as deflectors or coils of lenses). As a result, images generated by system 700 may not have the targeted image resolution since image resolution depends on characteristics of electron beams (e.g., where electron beams land on sample 732, size of electron beams, etc.).

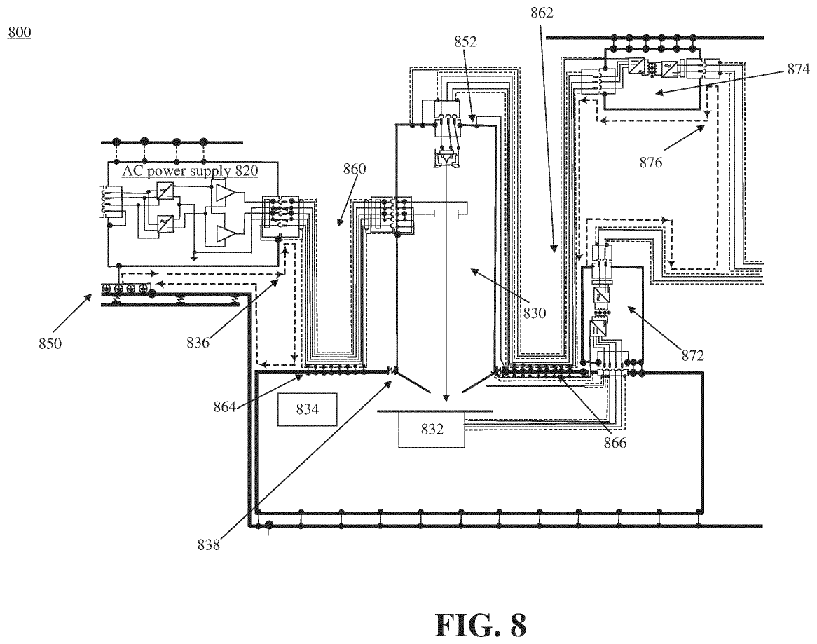

Reference is now made to FIG. 8, a schematic diagram of a charged particle system 800, consistent with embodiments of the present disclosure, including charged particle system 100 of FIG. 1 and charged particle system 400 of FIG. 4, circuit diagram 500A of FIG. 5A, and charged particle system 600 of FIG. 6. In some embodiments, charged particle system 800 may include an AC power source (e.g., AC power source 410 of FIG. 4, AC power source 610 of FIG. 6), an AC powered unit (e.g., an AC power supply, AC-powered load, AC-powered device such as an AC motor, etc. or any combination thereof), and a charged particle enclosure (e.g., charged particle enclosure 430 of FIG. 4) (e.g., SEM enclosure). In some embodiments, the AC powered unit may include an AC power supply 820 (e.g., AC power supply 420 of FIG. 4, AC power supply 620 of FIG. 6). The charged particle enclosure may include a charged particle column 830 (e.g., electron beam tool 104 of FIG. 1, electron beam tool 104 of FIG. 2A, electron beam tool 100B of FIG. 2B) (e.g., SEM column), a sample 832 (e.g., sample 208 of FIG. 2A, wafer 150 of FIG. 2B), and a main chamber 834 (e.g., main chamber 101 of FIG. 1) (e.g., a vacuum chamber). The plurality of enclosures, also referred to as the chassis of system 800, may be connected to ground references 850 and may enclose the AC power source, AC power supply 820, charged particle column 830, and main chamber 834. That is, in some embodiments, the AC power source, AC power supply 820, charged particle column 830, and main chamber 834 may be connected to ground references 850. In some embodiments, AC power supply 820 may include an EMI filter (e.g., EMI filter 422 of FIG. 4). In some embodiments, system 800 may include shielded power cables 860 coupled (e.g., electrically or mechanically coupled) between AC power supply 820 or associated electronic components (e.g., EMI filter) and charged particle column 830. System 800 may include shielded power cables 862 coupled (e.g., electrically or mechanically coupled) between charged particle column 830 and electronic components 874.

The current that flows through conductive components of system 800, such as shielded power cables 860 and 862 and electronic components 872 and 874, may generate magnetic fields within the space surrounding the conductive components. The magnetic fields induce noise currents, such as noise currents 836 and 876, in any conductive materials (e.g., signal conductors, electronic components, SEM frame, SEM enclosures, etc.).

In some embodiments, shielded power cables 860 may be electrically connected to main chamber 834 using bonding 864 to provide a low-impedance path for noise currents 836 to flow. For example, by electrically bonding shielded power cables 860 to main chamber 834, noise currents 836 may be directed into main chamber 834 rather than into charged particle column 830. In some embodiments, charged particle column 830 may be electrically isolated (but mechanically bonded) to main chamber 834 using an isolator 838 (e.g., insulating material). That is, charged particle column 830 may be mechanically coupled to and electrically isolated from main chamber 834 at a mechanical interface using isolator 838. Because noise currents 836 are directed into main chamber 834 due to bonding 864, isolator 838 is used to reduce noise current passing through charged particle column 830. That is, substantially zero noise currents generated by shielded power cables 860 may be injected into charged particle column 830.

In some embodiments, shielded power cables 862 may be electrically connected to main chamber 834 using bonding 866 to provide a low-impedance path for noise currents 876 to flow. For example, by electrically bonding shielded power cables 862 to main chamber 834, noise currents 876 may be directed into main chamber 834 rather than into charged particle column 830. In some embodiments, charged particle column 830 may be electrically isolated (but mechanically bonded) to main chamber 834 using isolator 838 (e.g., insulating material). That is, charged particle column 830 may be mechanically coupled to and electrically isolated from main chamber 834 at a mechanical interface using isolator 838. Because noise currents 876 are directed into main chamber 834 due to bonding 866, isolator 838 is used to reduce noise current passing through charged particle column 830. That is, substantially zero noise currents generated by shielded power cables 862 may be injected into charged particle column 830.

In some embodiments, charged particle column 830 may include a node 852 connected to the body of main chamber 834 or ground references 850. In some embodiments, any residual noise currents in charged particle column 830 may be directed to the body of main chamber 834 or node 852 to further reduce noise currents that may affect charged particle column 830 or other components of charged particle system 800.

In some embodiments, the area of the noise current loop formed by shielded power cables 860 or 862 between low-impedance bonding 864 or 866 and charged particle column 830 may be maintained as small as practically possible, typically below one square meter, to minimize inductive coupling to AC magnetic field noise.

As a result, ground loops of noise current may be substantially re-directed away from charged particle column 830, thus reducing interference into charged particle column 830 or other noise-sensitive components of charged particle system 800, and preventing the position of electron beams and images generated by the charged particle enclosure from being affected by noise currents. As a result, images generated by system 800 may achieve the targeted image resolution since image resolution depends on characteristics of electron beams (e.g., where electron beams land on sample 832, size of electron beams, etc.).

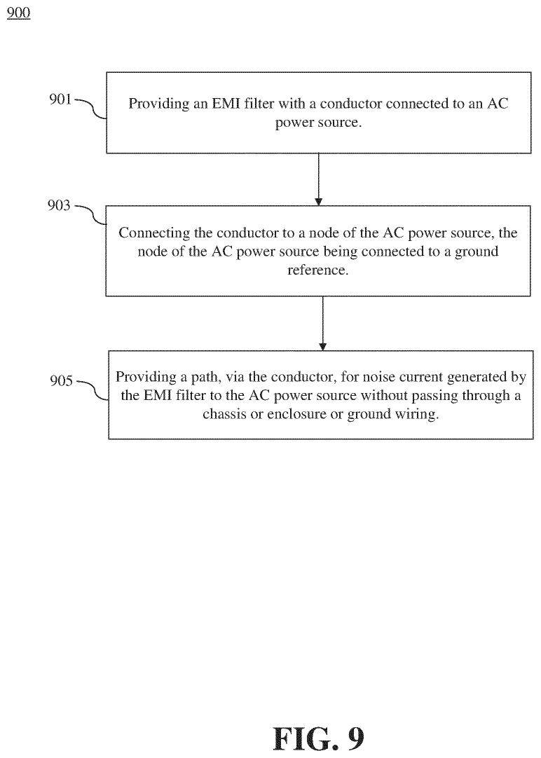

Reference is now made to FIG. 9, a flowchart illustrating an exemplary process 900 of reducing noise current, consistent with embodiments of the present disclosure. The steps of method 900 can be performed by a system (e.g., charged particle system 400 of FIG. 4, charged particle system 600 of FIG. 6) for purposes of illustration. It is appreciated that the illustrated method 900 can be altered to modify the order of steps and to include additional steps that may be performed by the system.

At step 901, a charged particle system (e.g., charged particle system 400 of FIG. 4, charged particle system 600 of FIG. 6) may provide an EMI filter (e.g., EMI filter 422 of FIG. 4) with a conductor (e.g., conductor 426 of FIG. 4, conductor 626 of FIG. 6) connected to an AC power source (e.g., AC power source 410 of FIG. 4, AC power source 610 of FIG. 6). In some embodiments, the charged particle system may include an AC power supply (e.g., AC power supply 420 of FIG. 4, AC power supply 620 of FIG. 6) and a charged particle enclosure (e.g., charged particle enclosure 430 of FIG. 4) (e.g., SEM enclosure). The charged particle enclosure may include a charged particle column (e.g., SEM column). In some embodiments, a chassis (e.g., chassis 440 of FIG. 4, chassis 540 of FIG. 5A, chassis 640 of FIG. 6) may be connected to a ground reference (e.g., ground reference 450 of FIG. 4, ground references 650 of FIG. 6) and may enclose the AC power source, the AC power supply, and the charged particle enclosure. The AC power supply may include the EMI filter, and the EMI filter may include capacitors (e.g., capacitors 421 of FIG. 4) and inductors. In some embodiments, the EMI filter may include at least three conductors (e.g., conductors 424, 425, and 426 of FIG. 4) (e.g., wires, cables, etc.). In some embodiments, the at least three conductors may be connected to the AC power source. In some embodiments, one conductor, of the at least three conductors, may be a power balance conductor that is electrically isolated from the chassis.

In some embodiments, any of the at least three conductors (e.g., conductors 624a, 625a, and 626a of FIG. 6) of the EMI filter may be electrically connected to the chassis (e.g., chassis 640 of FIG. 6). In some embodiments, when the at least one of the conductors of is electrically connected to the chassis, a first conductor may include an inductor (e.g., inductor 524 of FIG. 5A and FIG. 5B, inductor 624 of FIG. 6), a second conductor may include an inductor (e.g., inductor 525 of FIG. 5A and FIG. 5B, inductor 625 of FIG. 6), and a third conductor may include an inductor (e.g., inductor 526 of FIG. 5A and FIG. 5B, inductor 626 of FIG. 6).

At step 903, the power balance conductor may be connected to a node (e.g., node 412 of FIG. 4, node 612 of FIG. 6) of the AC power source. The node of the AC power source may be connected to the ground reference.

At step 905, when the power balance conductor is electrically isolated from the chassis, the power balance conductor may be configured to provide a dedicated path for noise currents (e.g., noise currents 427 of FIG. 4, capacitor leakage current generated by the EMI filter) generated by the EMI filter or other components of the AC power supply. In some embodiments, a sum current of the node of the AC power source may be substantially zero due to the sum current across the conductors being substantially zero. That is, the power balance conductor may remove noise currents from the chassis such that substantially zero noise currents are injected into the chassis or the ground reference 450. Instead, noise currents pass to the AC power source through the power balance conductor. As a result, ground noise currents and magnetic field noise generated by said currents injected into the charged particle system (e.g., into the charged particle enclosure, into a SEM column of the charged particle enclosure, into electronic components of the charged particle enclosure, etc.) may be reduced.

In some embodiments, when the at least one of three conductors is electrically connected to the chassis, the corresponding inductors may be magnetically coupled (e.g., have a common core) such that a sum of current flowing through the inductors is substantially zero. In some embodiments, the inductors may act as a noise current transformer (e.g., a choke) that forces the sum of current flowing through the inductors to be substantially zero. In some embodiments, as a result of the inductors, substantially zero current may pass through the node of the AC power source connected to the ground reference such that substantially zero noise current is injected into the chassis. As a result, ground noise currents and generated by said currents magnetic field noise injected into a charged particle enclosure (e.g., into a SEM column of the charged particle enclosure, into electronic components of the charged particle enclosure, etc.) may be reduced. For example, the currents flowing through the inductors may have substantially equal magnitudes and substantially opposite phases to noise currents generated by the EMI filter.

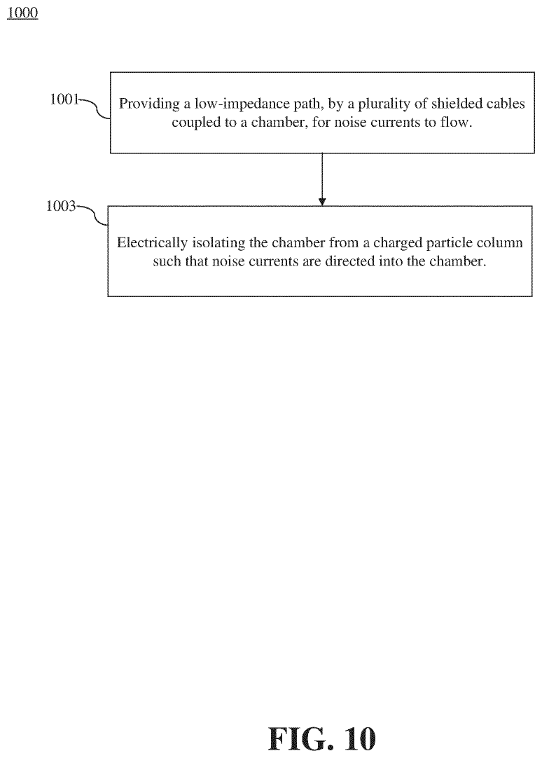

Reference is now made to FIG. 10, a flowchart illustrating an exemplary process 1000 of reducing noise current, consistent with embodiments of the present disclosure. The steps of method 1000 can be performed by a system (e.g., charged particle system 400 of FIG. 4, charged particle system 600 of FIG. 6, charged particle system 800 of FIG. 8) for purposes of illustration. It is appreciated that the illustrated method 1000 can be altered to modify the order of steps and to include additional steps that may be performed by the system.

At step 1001, shielded power or signal cables (e.g., shielded power cables 860 and 862 of FIG. 8) of a charged particle system (e.g., charged particle system 800 of FIG. 8) may be electrically connected to a main chamber (e.g., main chamber 834 of FIG. 8) using bonding (e.g., bonding 864 and 866 of FIG. 8) to provide a low-impedance path for noise currents (e.g., noise currents 836 and 876 of FIG. 8) to flow. For example, by electrically bonding the shielded power or signal cables to the main chamber, noise currents may be directed into the main chamber rather than into a charged particle column (e.g., charged particle column 830 of FIG. 8).

The current that flows through conductive components of the charged particle system, such as the shielded power cables and electronic components (e.g., electronic components 872 and 874 of FIG. 8), generate magnetic fields within the space surrounding the conductive components. The magnetic fields induce the above-described noise currents in any conductive materials (e.g., signal conductors, electronic components, SEM frame, SEM enclosures, etc.).

The area of the loop of power or signal cables between low-impedance bonding location and the SEM column is kept as small as practical, typically <1 square meter, to minimize inductive coupling to the AC magnetic field noise present within the system

At step 1003, the charged particle column may be electrically isolated (but mechanically bonded) to the main chamber using an isolator (e.g., isolator 838 of FIG. 8) (e.g., insulating material). That is, the charged particle column may be mechanically coupled to and electrically isolated from the main chamber at a mechanical interface using the isolator. Because the noise currents are directed into the main chamber due to the bonding, the isolator is used to reduce noise current passing through the charged particle column. That is, substantially zero noise currents generated by the shielded power cables may be injected into the charged particle column.

In some embodiments, the charged particle column may include a node (e.g., node 852 of FIG. 8) connected to the ground references. In some embodiments, any residual noise currents in the charged particle column may be directed to the node to further reduce noise currents that may affect the charged particle column or other components of the charged particle system.

As a result, ground loops of noise current may be re-directed away from the SEM column, thus minimizing interference into the charged particle column or other noise-sensitive components of the charged particle system, thereby preventing the position of electron beams and images generated by the charged particle enclosure from being affected by noise currents. As a result, images generated by the charged particle system may achieve the targeted image resolution since image resolution depends on characteristics of electron beams (e.g., where electron beams land on a sample, size of electron beams, etc.).

The embodiments may further be described using the following clauses:
1. A system comprising:
a chassis; and
an electromagnetic interference (EMI) filter comprising at least three conductors electrically connected to an alternating current (AC) power source,
wherein:
the at least three conductors include a first conductor that is electrically isolated from the chassis, the first conductor is electrically connected to a node of the AC power source, the node of the AC power source being electrically connected to a ground reference, and
the first conductor is configured to provide a path for noise current generated by the EMI filter to flow to the AC power source to enable the noise current to pass to the AC power source without passing through the chassis.
2. The system of clause 1, wherein the node of the AC power source is configured to have a sum current of substantially zero.
3. The system of any one of clauses 1-2, wherein the node of AC power source is connected to the chassis.
4. The system of any one of clauses 1-3, further comprising a charged particle column connected to the chassis.
5. The system of clause 4, wherein the first conductor is configured to provide the path for the noise current to enable the noise current to pass to the AC power source with reduced noise current passing through the charged particle column.
6. The system of any one of clauses 2-5, wherein the EMI filter comprises a node configured to receive the noise current generated by the EMI filter, the node being electrically connected to the conductor.
7. The system of any one of clauses 2-6, wherein the noise current injected into the chassis is substantially zero.
8. The system of any one of clauses 4-7, wherein the noise current injected into the charged particle column is substantially zero.
9. A system comprising:
a chassis; and
an electromagnetic interference (EMI) filter comprising at least three conductors electrically connected to an alternating current (AC) power source,
wherein:
at least one of the at least three conductors is electrically connected to the chassis and electrically connected to the AC power source,
each conductor of the at least three conductors includes an inductor, the inductors being magnetically coupled such that a sum of currents flowing through the inductors is substantially zero,
the at least three conductors include a first conductor that is electrically connected to a node of the AC power source, the node of the AC power source being electrically connected to a ground reference, and
the first conductor is configured to provide a path for noise current generated by the EMI filter to flow to the AC power source to enable the noise current to pass to the AC power source and to enable substantially zero noise current to pass through the chassis as a result of the inductors.
10. The system of clause 9, wherein the node of the AC power source is configured to have a sum current of substantially zero.
11. The system of any one of clauses 9-10, wherein the node of AC power source is connected to the chassis.
12. The system of any one of clauses 9-11, further comprising a charged particle column connected to the chassis.
13. The system of clause 12, wherein the first conductor is configured to provide the path for the noise current to enable the noise current to pass to the AC power source with reduced noise current passing through the charged particle column.
14. The system of any one of clauses 9-13, wherein the EMI filter comprises a node configured to receive the noise current generated by the EMI filter, the node being electrically connected to the first conductor.
15. The system of any one of clauses 9-14, wherein the currents flowing through the inductors have substantially equal magnitudes and substantially opposite phases to noise current generated by the EMI filter.
16. A system comprising:
a chamber;
a plurality of shielded cables that are electrically connected to the chamber to provide a low-impedance path for noise currents to flow; and
a column, wherein:
at a mechanical interface, the column is mechanically coupled to and electrically isolated from the chamber to prevent current from flowing through the mechanical interface between the column and the chamber, and
the chamber and the column are connected to a ground reference.
17. The system of clause 16, wherein noise current passing through the column is reduced as a result of the plurality of shielded cables being electrically connected to the chamber.
18. The system of any one of clauses 16-17, wherein the column is electrically isolated from the chamber via an insulating material between the chamber and the column.
19. The system of any one of clauses 16-18, wherein noise current present within the chamber and passing through the column is reduced as a result of the column being electrically isolated from the chamber.
20. The system of any one of clauses 16-19, wherein the column comprises a node connected to the ground reference.
21. The system of any one of clauses 16-20, wherein the column is a SEM column.
22. The system of any one of clauses 16-21, further comprising a chassis, and wherein:
the plurality of shielded cables are mechanically connected to an alternating current (AC) powered unit, the AC powered unit comprises an electromagnetic interference (EMI) filter,
the EMI filter comprises at least three conductors electrically connected to an AC power source,
the at least three conductors include a first conductor that is isolated from the chassis in the AC powered unit,
the first conductor is electrically connected to a node of the AC power source, the node of the AC power source being electrically connected to the ground reference, and
the first conductor is configured to provide a path for noise current generated by the EMI filter to the AC power source to enable the noise current to pass to the AC power source and to enable substantially zero noise current to pass through the chassis.
23. The system of clause 22, wherein the node of the AC power source is configured to have a sum current of substantially zero.
24. The system of any one of clauses 22-23, wherein the node of the AC power source is connected to the chassis.
25. The system of any one of clauses 22-24, wherein the first conductor is configured to provide the path for the noise current to enable the noise current to pass to the AC power source with reduced noise current passing through the column.
26. The system of any one of clauses 22-25, wherein the EMI filter comprises a node configured to receive the noise current generated by the EMI filter, the node being electrically connected to the conductor.
27. The system of any one of clauses 16-21, further comprising a chassis, and
wherein:
the plurality of shielded cables are mechanically connected to an electronic unit comprising electromagnetic interference (EMI) filter further comprising at least three conductors electrically connected to an alternating current (AC) power source,
at least one of the at least three conductors is electrically connected to the chassis in an AC powered unit and electrically connected to the AC power source,
each conductor of the at least three conductors includes an inductor, the inductors being magnetically coupled such that a sum of currents flowing through the inductors is substantially zero,
the at least three conductors include a first conductor that is electrically connected to a node of the AC power source, the node of the AC power source being electrically connected to a ground reference, and
the first conductor is configured to provide a path for noise current generated by the EMI filter to flow to the AC power source to enable the noise current to pass to the AC power source, and the inductors being magnetically coupled enables substantially zero noise current to pass through the chassis.
28. The system of clause 27, wherein the node of the AC power source is configured to have a sum current of substantially zero.
29. The system of any one of clauses 27-28, wherein the node of AC power source is connected to the chassis.
30. The system of any one of clauses 27-29, wherein the first conductor is configured to provide the path for the noise current to enable the noise current to pass to the AC power source with reduced noise current passing through the column.
31. The system of any one of clauses 27-30, wherein the EMI filter comprises a node configured to receive the noise current generated by the EMI filter, the node being electrically connected to the first conductor.
32. The system of any one of clauses 27-31, wherein the currents flowing through the inductors have substantially equal magnitudes and substantially opposite phases to noise current generated by the EMI filter.
33. A system comprising:
a chassis; and
an electromagnetic interference (EMI) filter comprising a conductor connected to an alternating current (AC) power source,
wherein:
the conductor is electrically isolated from the chassis,
the conductor is electrically connected to a node of the AC power source, the node of the AC power source being electrically connected to a ground reference, and
the conductor is configured to provide a path for noise current generated by the EMI filter to flow to the AC power source to enable the noise current to pass to the AC power source and substantially zero noise current is injected into the chassis.
34. The system of clause 33, wherein the node of the AC power source is configured to have a sum current of substantially zero.
35. The system of any one of clauses 33-34, wherein the node of AC power source is connected to the chassis.
36. The system of any one of clauses 33-35, further comprising a charged particle column connected to the chassis.
37. The system of clause 36, wherein the conductor is configured to provide the path for the noise current to enable the noise current to pass to the AC power source with reduced noise current passing through the charged particle column.
38. The system of any one of clauses 34-37, wherein the EMI filter comprises a node configured to receive the noise current generated by the EMI filter, the node being electrically connected to the conductor.
39. The system of any one of clauses 34-38, wherein the noise current injected into the chassis is substantially zero.
40. The system of any one of clauses 36-39, wherein the noise current injected into the charged particle column is substantially zero.
41. A system comprising:
a chassis; and
an electromagnetic interference (EMI) filter comprising a plurality of conductors electrically connected to an alternating current (AC) power source,
wherein:
at least one of the plurality of conductors is electrically connected to the chassis and electrically connected to the AC power source,
each conductor of the plurality of conductors includes an inductor, the inductors being magnetically coupled such that a sum of currents flowing through the inductors is substantially zero, the plurality of conductors comprises a first conductor that is electrically connected to a node of the AC power source, the node of the AC power source being electrically connected to a ground reference, and the first conductor is configured to provide a path for noise current generated by the EMI filter to flow to the AC power source to enable the noise current to pass to the AC power source, and the inductors being magnetically coupled enables substantially zero noise current to be injected into the chassis.
42. The system of clause 41, wherein the node of the AC power source is configured to have a sum current of substantially zero.
43. The system of any one of clauses 41-42, wherein the node of AC power source is connected to the chassis.
44. The system of any one of clauses 41-43, further comprising a charged particle column connected to the chassis.
45. The system of clause 44, wherein the first conductor is configured to provide the path for the noise current to enable the noise current to pass to the AC power source with reduced noise current passing through the charged particle column.
46. The system of any one of clauses 41-45, wherein the EMI filter comprises a node configured to receive the noise current generated by the EMI filter, the node being electrically connected to the first conductor.
47. The system of any one of clauses 41-46, wherein the currents flowing through the inductors have substantially equal magnitudes and substantially opposite phases to noise current generated by the EMI filter.
48. A system comprising:
a plurality of shielded cables that are electrically connected to a chamber to provide a path for noise currents to flow such that substantially zero of noise currents present in the plurality of shielded cables are injected into a column,
wherein:
at a mechanical interface, the column is mechanically connected to and electrically isolated from the chamber to prevent current from flowing through the mechanical interface between the column and the chamber, and
the chamber and the column are connected to a ground reference.
49. The system of clause 48, wherein noise current passing through the column is reduced as a result of the plurality of shielded cables being electrically connected to the chamber.
50. The system of any one of clauses 48-49, wherein the column is mechanically connected to and electrically isolated from the chamber via an insulating material between the chamber and the column.
51. The system of any one of clauses 48-50, wherein noise current present within the chamber and passing through the column is reduced as a result of the column being electrically isolated from the chamber.
52. The system of any one of clauses 48-51, wherein the column comprises a node connected to the ground reference.
53. The system of any one of clauses 48-52, wherein the column is a SEM column.
54. The system of any one of clauses 48-53, further comprising a chassis, and wherein:
the plurality of shielded cables are mechanically connected to an alternating current (AC) powered unit,
the AC powered unit comprises an electromagnetic interference (EMI) filter,
the EMI filter comprises at least three conductors electrically connected to an AC power source,
the at least three conductors include a first conductor that is isolated from the chassis in the AC powered unit,
the first conductor is electrically connected to a node of the AC power source, the node of the AC power source being electrically connected to the ground reference, and
the first conductor is configured to provide a path for noise current generated by the EMI filter to the AC power source to enable the noise current to pass to the AC power source and to enable substantially zero noise current to pass through the chassis.
55. The system of clause 54, wherein the node of the AC power source is configured to have a sum current of substantially zero.
56. The system of any one of clauses 54-55, wherein the node of the AC power source is connected to the chassis.
57. The system of any one of clauses 54-56, wherein the first conductor is configured to provide the path for the noise current to enable the noise current to pass to the AC power source with reduced noise current passing through the column.
58. The system of any one of clauses 54-57, wherein the EMI filter comprises a node configured to receive the noise current generated by the EMI filter, the node being electrically connected to the first conductor.
59. The system of any one of clauses 48-53, further comprising a chassis, and wherein:
the plurality of shielded cables are mechanically connected to an electronic unit comprising electromagnetic interference (EMI) filter further comprising at least three conductors electrically connected to an alternating current (AC) power source,
at least one of the at least three conductors is electrically connected to the chassis in an AC powered unit and electrically connected to the AC power source,
each conductor of the at least three conductors includes an inductor, the inductors being magnetically coupled such that a sum of currents flowing through the inductors is substantially zero,
the at least three conductors include a first conductor that is electrically connected to a node of the AC power source, the node of the AC power source being electrically connected to a ground reference, and
the first conductor is configured to provide a path for noise current generated by the EMI filter to flow to the AC power source to enable the noise current to pass to the AC power source, and the inductors being magnetically coupled enables substantially zero noise current to pass through the chassis.
60. The system of clause 59, wherein the node of the AC power source is configured to have a sum current of substantially zero.
61. The system of any one of clauses 59-60, wherein the node of AC power source is connected to the chassis.
62. The system of any one of clauses 59-61, wherein the first conductor is configured to provide the path for the noise current to enable the noise current to pass to the AC power source with reduced noise current passing through the column.
63. The system of any one of clauses 59-62, wherein the EMI filter comprises a node configured to receive the noise current generated by the EMI filter, the node being electrically connected to the first conductor.
64. The system of any one of clauses 59-63, wherein the currents flowing through the inductors have substantially equal magnitudes and substantially opposite phases to noise current generated by the EMI filter.
65. A system comprising:
a chassis; and
an alternating current (AC) powered unit comprising at least three conductors electrically connected to an AC power source,
wherein:
the at least three conductors include a first conductor that is electrically isolated from the chassis, the first conductor is electrically connected to a node of the AC power source, the node of the AC power source being electrically connected to a ground reference, and
the first conductor is configured to provide a path for noise current generated by the AC powered unit to flow to the AC power source to enable the noise current to pass to the AC power source without passing through the chassis.
66. The system of clause 65, wherein the node of the AC power source is configured to have a sum current of substantially zero.
67. The system of any one of clauses 65-66, wherein the node of AC power source is connected to the chassis.
68. The system of any one of clauses 65-67, further comprising a charged particle column connected to the chassis.
69. The system of clause 68, wherein the first conductor is configured to provide the path for the noise current to enable the noise current to pass to the AC power source with reduced noise current passing through the charged particle column.
70. The system of any one of clauses 66-69, further comprising an electromagnetic interference (EMI) filter, the EMI filter comprising a node configured to receive the noise current generated by the EMI filter, the node being electrically connected to the first conductor.
71. The system of any one of clauses 66-70, wherein the noise current injected into the chassis is substantially zero.
72. The system of any one of clauses 68-71, wherein the noise current injected into the charged particle column is substantially zero.
73. A system comprising:
a chassis; and
an alternating current (AC) powered unit comprising at least three conductors electrically connected to an AC power source,
wherein:
at least one of the at least three conductors is electrically connected to the chassis and electrically connected to the AC power source,
each conductor of the at least three conductors includes an inductor, the inductors being magnetically coupled such that a sum of currents flowing through the inductors is substantially zero,
the at least three conductors include a first conductor that is electrically connected to a node of the AC power source, the node of the AC power source being electrically connected to a ground reference, and the first conductor is configured to provide a path for noise current generated by the AC powered unit to flow to the AC power source to enable the noise current to pass to the AC power source, and the inductors being magnetically coupled enables the noise current to pass to the AC power source without passing through the chassis.
74. The system of clause 73, wherein the node of the AC power source is configured to have a sum current of substantially zero.
75. The system of any one of clauses 73-74, wherein the node of AC power source is connected to the chassis.
76. The system of any one of clauses 73-75, further comprising a charged particle column connected to the chassis.
77. The system of clause 76, wherein the first conductor is configured to provide the path for the noise current to enable the noise current to pass to the AC power source with reduced noise current passing through the charged particle column.
78. The system of any one of clauses 73-77, further comprising an electromagnetic interference (EMI) filter, the EMI filter comprising a node configured to receive the noise current generated by the EMI filter, the node being electrically connected to the first conductor.
79. The system of any one of clauses 73-78, wherein the currents flowing through the inductors have substantially equal magnitudes and substantially opposite phases to noise current generated by the EMI filter.
80. A system comprising:
a chassis; and
an alternating current (AC) powered unit comprising a conductor connected to an AC power source,
wherein:
the conductor is electrically isolated from the chassis,
the conductor is electrically connected to a node of the AC power source, the node of the AC power source being electrically connected to a ground reference, and
the conductor is configured to provide a path for noise current generated by the AC powered unit to flow to the AC power source to enable the noise current to pass to the AC power source and substantially zero noise current is injected into the chassis.
81. The system of clause 80, wherein the node of the AC power source is configured to have a sum current of substantially zero.
82. The system of any one of clauses 80-81, wherein the node of AC power source is connected to the chassis.
83. The system of any one of clauses 80-82, further comprising a charged particle column connected to the chassis.
84. The system of clause 83, wherein the first conductor is configured to provide the path for the noise current to enable the noise current to pass to the AC power source with reduced noise current passing through the charged particle column.
85. The system of any one of clauses 81-84, further comprising an electromagnetic interference (EMI) filter, the EMI filter comprising a node configured to receive the noise current generated by the EMI filter, the node being electrically connected to the first conductor.
86. The system of any one of clauses 81-85, wherein the noise current injected into the chassis is substantially zero.
87. The system of any one of clauses 83-86, wherein the noise current injected into the charged particle column is substantially zero.
88. A system comprising:
a chassis; and
an alternating current (AC) powered unit comprising a plurality of conductors electrically connected to an AC power source,
wherein:
at least one of the plurality of conductors is electrically connected to the chassis and electrically connected to the AC power source,
each conductor of the plurality of conductors includes an inductor, the inductors being magnetically coupled such that a sum of currents flowing through the inductors is substantially zero,
the plurality of conductors comprises a first conductor that is electrically connected to a node of the AC power source, the node of the AC power source being electrically connected to a ground reference, and
the first conductor is configured to provide a path for noise current generated by the AC powered unit to flow to the AC power source to enable the noise current to pass to the AC power source, and the inductors being magnetically coupled enables substantially zero noise current to be injected into the chassis.
89. The system of clause 88, wherein the node of the AC power source is configured to have a sum current of substantially zero.
90. The system of any one of clauses 88-89, wherein the node of AC power source is connected to the chassis.
91. The system of any one of clauses 88-90, further comprising a charged particle column connected to the chassis.
92. The system of clause 91, wherein the first conductor is configured to provide the path for the noise current to enable the noise current to pass to the AC power source with reduced noise current passing through the charged particle column.
93. The system of any one of clauses 88-92, further comprising an electromagnetic interference (EMI) filter, the EMI filter comprising a node configured to receive the noise current generated by the EMI filter, the node being electrically connected to the first conductor.
94. The system of any one of clauses 88-93, wherein the currents flowing through the inductors have substantially equal magnitudes and substantially opposite phases to noise current generated by the EMI filter.
95. The system of any one of clauses 1-8, wherein the EMI filter comprises at least one capacitor.
96. The system of clause 41, wherein the noise current comprises ground leakage current from the at least one capacitor.
97. The system of any one of clauses 9-15, wherein the EMI filter comprises at least one capacitor.
98. The system of clause 97, wherein the noise current comprises ground leakage current from the at least one capacitor.
99. The system of any one of clauses 22-32, wherein the EMI filter comprises at least one capacitor.
100. The system of clause 99, wherein the noise current comprises ground leakage current from the at least one capacitor.
101. The system of any one of clauses 33-40, wherein the EMI filter comprises at least one capacitor.
102. The system of clause 101, wherein the noise current comprises ground leakage current from the at least one capacitor.
103. The system of any one of clauses 41-47, wherein the EMI filter comprises at least one capacitor.
104. The system of clause 103, wherein the noise current comprises ground leakage current from the at least one capacitor.
105. The system of any one of clauses 54-64, wherein the EMI filter comprises at least one capacitor.
106. The system of clause 105, wherein the noise current comprises ground leakage current from the at least one capacitor.
107. The system of any one of clauses 70-72, wherein the EMI filter comprises at least one capacitor.
108. The system of clause 107, wherein the noise current comprises ground leakage current from the at least one capacitor.
109. The system of any one of clauses 78-79, wherein the EMI filter comprises at least one capacitor.
110. The system of clause 107, wherein the noise current comprises ground leakage current from the at least one capacitor.
111. The system of any one of clauses 85-87, wherein the EMI filter comprises at least one capacitor.
112. The system of clause 111, wherein the noise current comprises ground leakage current from the at least one capacitor.
113. The system of any one of clauses 93-94, wherein the EMI filter comprises at least one capacitor.
114. The system of clause 113, wherein the noise current comprises ground leakage current from the at least one capacitor.
115. The system of any one of clauses 22-32, 99, or 100, wherein the AC powered unit comprises any of an AC power supply, an AC-powered load, an AC-powered device, an AC motor, or any combination thereof.
116. The system of any one of clauses 54-64, 105, or 106, wherein the AC powered unit comprises any of an AC power supply, an AC-powered load, an AC-powered device, an AC motor, or any combination thereof.
117. The system of any one of clauses 65-72, 107, or 108, wherein the AC powered unit comprises any of an AC power supply, an AC-powered load, an AC-powered device, an AC motor, or any combination thereof.
118. The system of any one of clauses 73-79, 109, or 110, wherein the AC powered unit comprises any of an AC power supply, an AC-powered load, an AC-powered device, an AC motor, or any combination thereof.
119. The system of any one of clauses 80-87, 111, or 112, wherein the AC powered unit comprises any of an AC power supply, an AC-powered load, an AC-powered device, an AC motor, or any combination thereof.
120. The system of any one of clauses 88-94, 113, or 114, wherein the AC powered unit comprises any of an AC power supply, an AC-powered load, an AC-powered device, an AC motor, or any combination thereof.

It will be appreciated that the embodiments of the present disclosure are not limited to the exact construction that has been described above and illustrated in the accompanying drawings, and that various modifications and changes may be made without departing from the scope thereof.

1. A system comprising:
a chassis; and
an electromagnetic interference (EMI) filter comprising at least three conductors electrically connected to an alternating current (AC) power source,
wherein:
the at least three conductors include a first conductor that is electrically isolated from the chassis,
the first conductor is electrically connected to a node of the AC power source, the node of the AC power source being electrically connected to a ground reference, and
the first conductor is configured to provide a path for noise current generated by the EMI filter to flow to the AC power source to enable the noise current to pass to the AC power source without passing through the chassis.

2. The system of claim 1, wherein the node of the AC power source is configured to have a sum current of substantially zero.

3. The system of claim 1, wherein the node of AC power source is connected to the chassis.

4. The system of claim 1, further comprising a charged particle column connected to the chassis.

5. The system of claim 4, wherein the first conductor is configured to provide the path for the noise current to enable the noise current to pass to the AC power source with reduced noise current passing through the charged particle column.

6. The system of claim 2, wherein the EMI filter comprises a node configured to receive the noise current generated by the EMI filter, the node being electrically connected to the conductor.

7. The system of claim 2, wherein the noise current injected into the chassis is substantially zero.

8. The system of claim 4, wherein the noise current injected into the charged particle column is substantially zero.

9. The system of claim 1, wherein the EMI filter comprises at least one capacitor.

10. A system comprising:
a chamber;
a plurality of shielded cables that are electrically connected to the chamber to provide a low-impedance path for noise currents to flow; and
a column, wherein:
at a mechanical interface, the column is mechanically coupled to and electrically isolated from the chamber to prevent current from flowing through the mechanical interface between the column and the chamber, and
the chamber and the column are connected to a ground reference.

11. The system of claim 10, wherein noise current passing through the column is reduced as a result of the plurality of shielded cables being electrically connected to the chamber.

12. The system of claim 10, wherein the column is electrically isolated from the chamber via an insulating material between the chamber and the column.

13. The system of claim 10, wherein noise current present within the chamber and passing through the column is reduced as a result of the column being electrically isolated from the chamber.

14. The system of claim 10, wherein the column comprises a node connected to the ground reference.

15. The system of claim 10, wherein the column is a SEM column.

16. The system of claim 10, further comprising a chassis, and wherein:
the plurality of shielded cables are mechanically connected to an alternating current (AC) powered unit,
the AC powered unit comprises an electromagnetic interference (EMI) filter,
the EMI filter comprises at least three conductors electrically connected to an AC power source,
the at least three conductors include a first conductor that is isolated from the chassis in the AC powered unit,
the first conductor is electrically connected to a node of the AC power source, the node of the AC power source being electrically connected to the ground reference, and
the first conductor is configured to provide a path for noise current generated by the EMI filter to the AC power source to enable the noise current to pass to the AC power source and to enable substantially zero noise current to pass through the chassis.

17. The system of claim 16, wherein the node of the AC power source is configured to have a sum current of substantially zero.

18. The system of claim 16, wherein the node of the AC power source is connected to the chassis.

19. The system of claim 16, wherein the first conductor is configured to provide the path for the noise current to enable the noise current to pass to the AC power source with reduced noise current passing through the column.

20. A system comprising:
a plurality of shielded cables that are electrically connected to a chamber to provide a path for noise currents to flow such that substantially zero of noise currents present in the plurality of shielded cables are injected into a column,
wherein:
at a mechanical interface, the column is mechanically connected to and electrically isolated from the chamber to prevent current from flowing through the mechanical interface between the column and the chamber, and
the chamber and the column are connected to a ground reference.
